(19) United States
(12) Patent Application Publication
(10) Pub. No.: US 2013/0004175 A1
(43) Pub. Date: Jan. 3, 2013

(54) OPTICAL MODULATOR

(75) Inventors: Tiago Silveira, Sangalhos (PT); Ana Ferreira, Borralha (PT)

(73) Assignee: NOKIA SIEMENS NETWORKS OY, ESPOO (FI)

(21) Appl. No.: 13/634,324

(22) PCT Filed: Feb. 22, 2011
(86) PCT No.: PCT/EP2011/052617

§ 371 Date: Sep. 12, 2012

(30) Foreign Application Priority Data
Mar. 12, 2010 (EP) 101 56 342

(51) Int. Cl. H01S 5/50; H04J 14/02

(52) U.S. Cl. 398/79; 359/276; 359/344

(57) ABSTRACT

An optical modulator and a method for operating the optical modulator are provided, the optical modulator contains at least two semiconductor optical amplifier sections that are arranged in a cascaded structure. An information signal is applicable to one of the semiconductor optical amplifier sections and an inverse information signal is applicable to another of the semiconductor optical amplifier sections. In addition, a communication system containing at least one such modulator is suggested.

The invention relates to an optical modulator and to a method for operating an optical modulator. In addition, a communication system comprising at least one such modulator is suggested.

The fast growth of data exchange has led to an increasing demand for transmission bandwidth. Dense wavelength division multiplexing (DWDM) networks offer high capacity transmission, both in core and/or backhaul and access and/or metro networks.

Cost efficient DWDM networks are enabled by the use of advanced modulation formats, such as differential binary phase shift keying (DPSK), differential quadrature phase shift keying (DQPSK), duobinary, carrier-suppressed return-to-zero (CS-RZ), or optical single sideband (OSSB), etc.

To generate optical signals with such modulation formats, it is required to control the phase and amplitude of the optical signal. For such purpose Mach-Zehnder modulators (MZMs) are commonly employed; however, the MZMs have high insertion losses (around 6 dB) and are considered expensive for access and radio-over-fiber applications. Directly modulated lasers have been utilized for such purposes, but the resulting amplitude modulated signals also present undesired phase distortion or reduced amplitude extinction ratio.

The problem to be solved is to avoid the disadvantages stated above and in particular to provide a cost-efficient solution of a modulator that is capable of modulating the amplitude or the amplitude and phase. The modulator may further be based on SOA technology.

This problem is solved according to the features of the independent claims. Further embodiments result from the depending claims.

In order to overcome this problem, an optical modulator is provided
comprising at least two semiconductor optical amplifier sections that are arranged in a cascaded structure;
wherein an information signal is applicable to one of the semiconductor optical amplifier sections and an inverse information signal is applicable to another of the semiconductor optical amplifier sections.

It is noted that the cascaded structure may refer to a series of SOAs, where each SOA sends its output to the input of the next SOA in a daisy chain.

Hence, the modulator may provide amplitude modulation with negligible phase modulation based on a semiconductor optical amplifier (SOA) structure. This modulator allows for an independent control of the optical signal amplitude modulation and phase modulation in a single device.

This approach facilitates optical modulators of low-cost and with low insertion losses, which are a key issue in access and radio over fiber (RoF) DWDM networks. Providing an independent control over the optical phase and amplitude enables generation of optical signals with advanced modulation formats. The solution suggested in particular supports pure amplitude modulated optical signals or optical signals with independent amplitude and phase modulation. As the structure is an SOA, an overall optical gain can be expected.

In an embodiment, the modulator may be used for or it may facilitate
OSSB modulation;
DPSK modulation;
DQPSK modulation;
CS-RZ modulation;
substantially chirp-free OOK modulation.

In another embodiment, the modulator comprises two, three or four semiconductor optical amplifier sections.

Basically, several SOA sections could be arranged in cascaded structure. Preferably, two SOA sections are used, a first one for the information signal to be applied and a second one for the inverse information signal—preferably multiplied by a factor K—to be applied.

In a further embodiment, the inverse information signal is multiplied by a factor K.

In a next embodiment, the factor K amounts to K=α₂/α₁, wherein α₁ describes a ratio between the amplitude modulation and the phase modulation of a first semiconductor optical amplifier section and α₂ describes a ratio between the amplitude modulation and the phase modulation of a second semiconductor optical amplifier section.

It is noted that α₂, α₁ are also referred to as linewidth enhancement factors. It is also noted that the modulator may comprise in particular two semiconductor optical amplifier sections.

It is also noted that in case α₁>>α₂ and K<<1, the modulator does predominately show amplitude modulation and no (or nearly no) phase modulation.

It is also an embodiment that the ratio between the amplitude modulation and the phase modulation of the first semiconductor optical amplifier section and the ratio between the amplitude modulation and the phase modulation of the second semiconductor optical amplifier section are controlled by, e.g., a bias current or by amplifier design.

Said bias current may be a bias DC current.

Pursuant to another embodiment, the semiconductor optical amplifier section driven by bias current of lower amplitude is arranged in prior to a subsequent semiconductor optical amplifier section that is driven by the bias current of higher amplitude.

According to an embodiment, the modulator is used in an access network or in a radio-over-fiber network.

According to another embodiment, at least two subsequent semiconductor optical amplifier sections are arranged for phase modulation purposes.

Hence, the information signal may be an electrical signal driving the phase modulation stage.

In yet another embodiment, at least two subsequent semiconductor optical amplifier sections are arranged for amplitude modulation purposes.

Hence, the information signal may be an electrical signal driving the amplitude modulation stage.

According to a next embodiment, the information signal comprises at least one of the following:
an electrical signal driving the phase modulation stage;
an electrical signal driving the amplitude modulation stage.

Hence, the information signal may comprise a combination of an electrical signal driving the phase modulation and another electrical signal driving the amplitude modulation; the electrical signals are applied to at least two semiconductor optical amplifier sections, wherein if the electrical signal is applied to one semiconductor optical amplifier section, the inverse electrical signal (together with the factor K) is applied to another semiconductor optical amplifier section. This allows efficient amplitude modulation or amplitude and phase modulation of an optical signal. Hence, for that purpose at least two semiconductor optical amplifier sections are required as combined electrical signals could be applied to any semiconductor optical amplifier section.

The problem stated above is also solved by a method for operating an optical modulator comprising at least two semiconductor optical amplifier sections that are arranged in a cascaded structure, wherein an information signal is applied to one of the semiconductor optical amplifier sections and an inverse information signal is applied to another of the semiconductor optical amplifier sections.

It is noted that the features described with regard to the modulator apply accordingly for said method. Basically, the method can be used to operate the modulator. In particular, a processing unit can be provided that is arranged such that the modulator is operated accordingly. The processing unit can comprise at least one, in particular several means that are arranged to execute the steps of the method described herein. The means may be logically or physically separated; in particular several logically separate means could be combined in at least one physical unit.

Said processing unit may comprise at least one of the following: a processor, a microcontroller, a hard-wired circuit, an ASIC, an FPGA, a logic device.

According to an embodiment, the inverse information signal is multiplied by a factor K and the factor K results in K=α₂/α₁, wherein α₁ describes a ratio between the amplitude modulation and the phase modulation of a first semiconductor optical amplifier section and α₂ describes a ratio between the amplitude modulation and the phase modulation of a second semiconductor optical amplifier section.

Pursuant to yet an embodiment, the information signal comprises at least one of the following:
an electrical signal driving the phase modulation;
an electrical signal driving the amplitude modulation.

Furthermore, the problem stated above is solved by a communication system comprising at least one modulator as described herein.

Embodiments of the invention are shown and illustrated in the following figures:

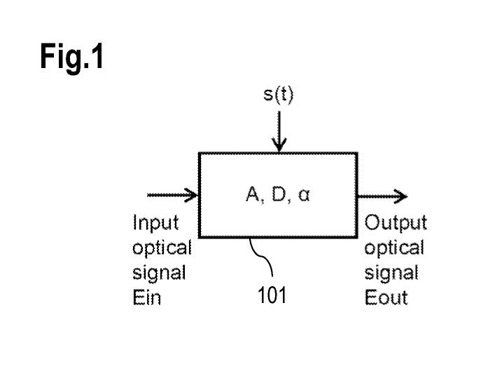

FIG. 1 shows a schematic of a semiconductor optical amplifier (SOA) section;

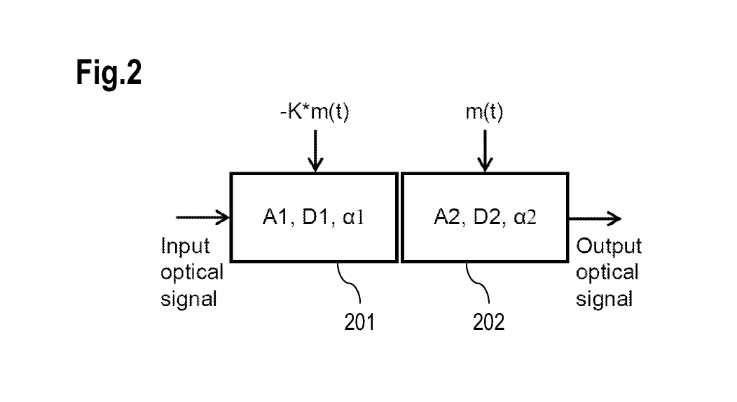

FIG. 2 shows a SOA structure comprising two sections to obtain amplitude modulation, wherein an information signal is applied to a first section and the inverted information signal multiplied by a factor K is applied to a second section of the SOA structure;

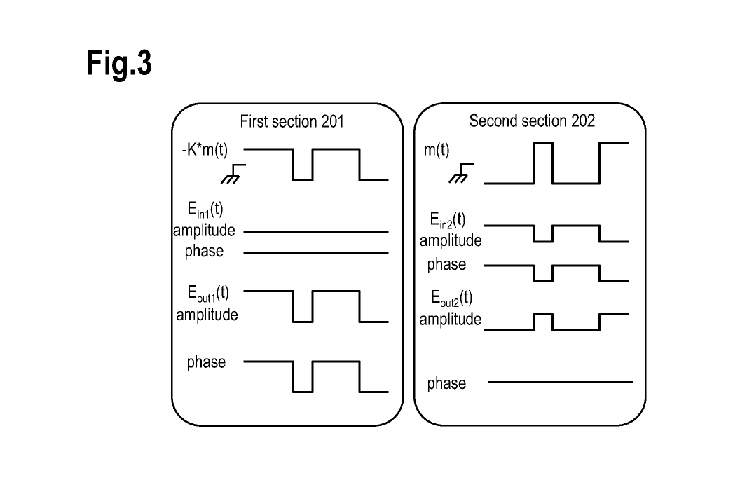

FIG. 3 shows a schematic diagram depicting an operation scheme of a SOA structure with two sections to obtain amplitude modulation;

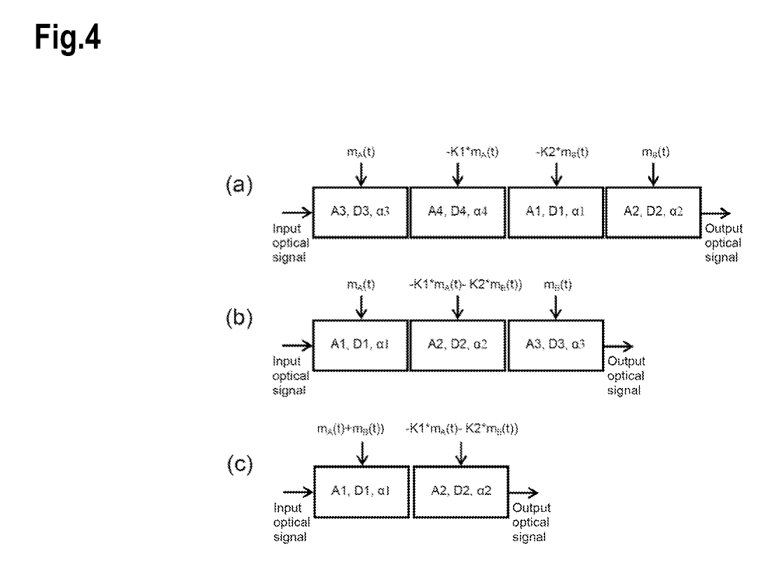

FIG. 4 shows three schematics of semiconductor optical amplifiers to obtain controlled AM and PM comprising four, three and two sections.

It is suggested using a multi-electrode SOA structure to generate a pure AM optical signal or an optical signal with independent AM and PM in particular with an optical gain.

Thus, optical signals may be generated with advanced modulation formats (e.g., OSSB, DPSK) for access or RoF networks.

### Amplitude Modulation Only: Conceptual Approach

FIG. 1 shows a schematic of a semiconductor optical amplifier section 101. The amplifier section 101 induces gain (amplitude) and phase modulation over an input signal Eᵢₙ as a function of an AC-coupled driving signal s(t). For simplicity reasons, a DC-driving signal (offset) is not shown in FIG. 1.

An output signal Eₒᵤₜ of the semiconductor optical amplifier section 101 can be described as

$${E}_{out} ( t ) = {E}_{in} ( t ) \cdot \sqrt{G} \cdot exp \{ j \cdot \frac{α}{2} \cdot ( ln ( G ) + γ ) \} \qquad ( 1 )$$

wherein
Eᵢₙ(t) corresponds to an electrical field of the optical signal at the input of the semiconductor optical amplifier section 101;
Eₒᵤₜ(t) corresponds to an electrical field of the optical signal at the output of the semiconductor optical amplifier section 101;
G is an optical power gain;
α describes a ratio between the amplitude modulation and the phase modulation (α is also known as linewidth enhancement factor); and
γ is a rate of cavity loss caused by facet and waveguide losses.

In case the input signal varies in a scale of time below a SOA recovery time and the input power is low to prevent gain saturation, it can be assumed that the gain is based on the modulating signal s(t) as follows:

G=exp[A(s(t)+D)] (2)

wherein A and D are constants that describe the relationship between the amplifier gain and the modulating signal.

The output signal can then be described as:

$${E}_{out} ( t ) = {E}_{in} ( t ) \cdot \sqrt{exp [ A \cdot ( s ( t ) + D ) ]} \cdot exp \{ j \cdot \frac{α}{2} \cdot [ A \cdot ( s ( t ) + D ) + γ ] \} \qquad ( 3 )$$

FIG. 2 shows a SOA structure comprising two sections 201 and 202 to obtain amplitude modulation. An information signal m(t) is applied to the section 202 and the inverted information signal −m(t) multiplied by a factor K is applied to the section 201. The signal at the output of the SOA structure can be described by applying equation (1) to the two sections 201, 202:

$${E}_{out} ( t ) = {E}_{in} ( t ) \cdot \sqrt{exp [ {A}_{1} \cdot ( - K \cdot m ( t ) + {D}_{1} ) ]} \cdot exp \{ j \cdot \frac{{α}_{3}}{2} \cdot [ {A}_{1} \cdot ( - K \cdot m ( t ) + {D}_{1} ) + {γ}_{1} ] \} \cdot \cdot \sqrt{exp [ {A}_{2} \cdot ( m ( t ) + {D}_{2} ) ]} \cdot exp \{ j \cdot \frac{{α}_{2}}{2} \cdot [ {A}_{2} \cdot ( m ( t ) + {D}_{2} ) + {γ}_{2} ] \} \qquad ( 4 )$$

wherein K (K<1) represents an attenuation.

Assuming that
A₂≈A₁=A;
D₂≈D₁=D; and
γ₁≈γ₂=γ
   and rearranging equation (4) results in:

$${E}_{out} ( t ) \approx {E}_{in} ( t ) \cdot \sqrt{exp [ A \cdot ( m ( t ) ( 1 - K ) + 2 \cdot D ) ]} \cdot \cdot exp \{ j \cdot [ m ( t ) \cdot \frac{A}{2} ( - K \cdot {α}_{1} + {α}_{2} ) + \frac{A \cdot D}{2} ( {α}_{1} + {α}_{2} ) + \frac{γ}{2} ( {α}_{1} + {α}_{2} ) ] \} \qquad ( 5 )$$

In order to achieve AM only, the following condition is to be met

−K·α₁+α₂=0

which can be achieved by controlling the factor K as follows:

$$K = \frac{{α}_{2}}{{α}_{1}}$$

In case
α₁>>α₂;
K<<1
   equation (3) can be arranged to

$${E}_{out} ( t ) \approx {E}_{in} ( t ) \cdot \sqrt{exp [ A \cdot ( m ( t ) + 2 \cdot D ) ]} \cdot exp \{ j \cdot \frac{{α}_{1}}{2} ( A \cdot D + γ ) \} \qquad ( 6 )$$

It can be shown that equation (6) does not have any phase modulation; furthermore, the optical power is modulated by the information signal m(t).

In case

A·m(t)<<1

the optical power is modulated with the data signal and the output signal amounts to

$${E}_{out} ( t ) \approx {E}_{in} ( t ) \cdot \sqrt{exp [ A \cdot 2 \cdot D ] \cdot ( 1 + A \cdot m ( t ) )} \cdot exp \{ j \cdot \frac{{α}_{1}}{2} ( A \cdot D + γ ) \} \qquad ( 7 )$$

The operation of this scheme is illustrated in FIG. 3 for square waveforms. As can be seen, at an input Eᵢₙ₁ of the first section 201 there is no intensity or phase modulation. After the first section (i.e., at an output Eₒᵤₜ₁ of the first section 201) the intensity and phase of the optical signal are modulated with the inverse of the attenuated input data signal. This signal is then fed to the second section 202. The data signal is driving this section, but with a higher amplitude than in the first section 201.

By properly controlling the attenuation in the first section 201 in relation to α₁/α₂, cancellation of the PM is achieved, but the AM is preserved.

On the other hand, if A·m(t) is not negligible (when compared to 1), the data signals driving the SOA can be pre-distorted with a logarithmic function so that the output signal power is still proportional to the data signal.

### Amplitude Modulation Only: Exemplary Implementation

The proposed solution suggests a SOA with two active sections or two cascaded SOA sections comprising distinct linewidth enhancement factors α₁, α₂. The linewidth enhancement factors can be controlled by a bias DC current. The relation between linewidth enhancement factor and bias current is described, e.g., in T. N. Nielsen, et al., “Cancellation of inherent AM in semiconductor optical amplifier phase modulators”, in Electron. Lett., vol. 28, no. 3, 30.01.1992, pp. 235-236 or in N. Storkfelt et al., “Measurement of carrier lifetime and linewidth enhancement factor for 1.5-mu m ridge-waveguide laser amplifier”, in IEEE Photon. Technol. Lett., vol. 3, no. 7, July 1991, pp. 632-634. For such purpose, a SOA with two electrodes or two cascaded SOAs may be employed.

It is noted that since the SOA bias current is different in the two electrodes, so are the A and D parameters; therefore the K factor can be calculated as follows:

$$K = \frac{{α}_{1} {A}_{1}}{{α}_{2} {A}_{2}}$$

The solution presented herein in particular adjusts the K factor to minimize the AM.

The order of the two sections 201, 202 can be changed; however, preferably, the section driven by the electrical signal with lower amplitude may be the first section, which is beneficial in order to reduce signal distortion due to Self-Gain and Self-Phase modulation.

### Independent Amplitude and Phase Modulation

It is further suggested generating an optical signal with independent AM and PM. This objective may be met by using a semiconductor optical amplifier comprising four sections or four cascaded SOAs.

In the first two sections, PM may be conducted as described in T. N. Nielsen, et al., “Cancellation of inherent AM in semiconductor optical amplifier phase modulators”, in Electron. Lett., vol. 28, no. 3, 30.01.1992, pp. 235-236.

In the remaining two sections, AM can be conducted accordingly as described above under “amplitude modulation only”.

The order of sections performing PM and AM is interchangeable. Nevertheless, the order indicated above may be preferred.

FIG. 4 shows three schematics of semiconductor optical amplifiers to obtain controlled AM and PM comprising four, three and two sections. A signal m_{A}(t) is an electrical signal driving the PM and a signal m_{B}(t) is an electrical signal driwing the AM. As a result of this proposal, it is possible to perform AM and PM in the same device, with gain.

The number of semiconductor optical amplifier sections can be reduced from four to three or two as shown in (a) to (c) of FIG. 4.

The exemplary implementations (a) and (b) may be preferred, because they may be more cost efficient, as the SOA can be directly integrated with the laser source. Furthermore, amplitude and phase modulation can be controlled independently. Since semiconductor sections are used, optical gain is expected, which is a key factor for low cost access networks or passive optical networks.

### LIST OF ABBREVIATIONS

AC Alternating Current
AM Amplitude Modulation
CS-RZ Carrier-Suppressed Return-to-Zero
DC Direct Current
DPSK Differential PSK
DQPSK Differential QPSK
DWDM Dense Wavelength Division Multiplexing
MZM Mach-Zehnder Modulator
OOK On-Off Keying
OSSB optical Single Sideband
PM Phase Modulation
PSK Phase Shift Keying
QPSK Quadrature PSK
RoF Radio over Fiber
SOA Semiconductor Optical Amplifier

1-15. (canceled)

16. An optical modulator, comprising:
at least two semiconductor optical amplifier sections disposed in a cascaded manner, an information signal is applicable to a first of said semiconductor optical amplifier sections and an inverse information signal is applicable to a second of said semiconductor optical amplifier sections.

17. The modulator according to claim 16, wherein the optical modulator is used for at least one of OSSB modulation, DPSK modulation, DQPSK modulation, CS-RZ modulation, or substantially chirp-free OOK modulation.

18. The modulator according to claim 16, wherein said at least two semiconductor optical amplifier sections is two semiconductor optical amplifier sections.

19. The modulator according to claim 16, wherein the inverse information signal is multiplied by a factor K.

20. The modulator according claim 19, wherein the factor K amounts to K=α₂/α₁,
wherein α₁ describes a ratio between an amplitude modulation and a phase modulation of said first semiconductor optical amplifier section and α₂ describes a ratio between an amplitude modulation and a phase modulation of said second semiconductor optical amplifier section.

21. The modulator according to claim 20, wherein a ratio between the amplitude modulation and the phase modulation of said first semiconductor optical amplifier section and a ratio between the amplitude modulation and the phase modulation of said second semiconductor optical amplifier section are controlled by a bias current or by amplifier design.

22. The modulator according to claim 21, wherein said semiconductor optical amplifier section driven by a first bias current of lower amplitude is disposed prior to a subsequent said semiconductor optical amplifier section that is driven by a second bias current of higher amplitude.

23. The modulator according to claim 16, wherein the optical modulator is used in an access network or in a radio-over-fiber network.

24. The modulator according to claim 16, further comprising at least two subsequent semiconductor optical amplifier sections disposed for phase modulation purposes.

25. The modulator according to claim 16, further comprising at least two subsequent semiconductor optical amplifier sections disposed for amplitude modulation purposes.

26. The modulator according to claim 16, wherein the information signal contains at least one of the following:
an electrical signal driving a phase modulation stage; and
an electrical signal driving a amplitude modulation stage.

27. The modulator according to claim 16, wherein said at least two semiconductor optical amplifier sections is three semiconductor optical amplifier sections.

28. The modulator according to claim 16, wherein said at least two semiconductor optical amplifier sections is four semiconductor optical amplifier sections.

29. A method for operating an optical modulator containing at least two semiconductor optical amplifier sections disposed in a cascaded manner, which comprises the steps of:
applying an information signal to a first of the semiconductor optical amplifier sections; and
applying an inverse information signal to a second of the semiconductor optical amplifier sections.

30. The method according to claim 29, which further comprises:
multiplying the inverse information signal by a factor K, wherein the factor K results in K=α₂/α₁,
where α₁ describes a ratio between an amplitude modulation and a phase modulation of the first semiconductor optical amplifier section and α₂ describes a ratio between an amplitude modulation and a phase modulation of the second semiconductor optical amplifier section.

31. The method according to claim 27, wherein the information signal comprises at least one of the following:
an electrical signal driving the phase modulation; and
an electrical signal driving the amplitude modulation.

32. A communication system, comprising:
an optical modulator containing at least two semiconductor optical amplifier sections disposed in a cascaded manner, an information signal is applicable to a first of said semiconductor optical amplifier sections and an inverse information signal is applicable to a second of said semiconductor optical amplifier sections.
